(19) United States
(12) Patent Application Publication
(10) Pub. No.: US 2026/0191030 A1
(43) Pub. Date: Jul. 2, 2026

(54) SEMICONDUCTOR DEVICE

(71) Applicant: ROHM CO., LTD., Kyoto-shi (JP)

(72) Inventor: Hiroaki AOYAMA, Kyoto-shi (JP)

(21) Appl. No.: 19/543,245

(22) Filed: Feb. 18, 2026

Related U.S. Application Data
(63) Continuation of application No. PCT/JP2024/027361, filed on Jul. 31, 2024.

(30) Foreign Application Priority Data
Aug. 25, 2023 (JP) 2023-136915

(51) Int. Cl. H10W 70/40; H10W 74/10; H10W 90/00

(52) U.S. Cl. CPC H10W 70/415; H10W 74/111; H10W 90/726

(57) ABSTRACT

A semiconductor device includes a first terminal, a second terminal, a third terminal, a fourth terminal, a first lead, a second lead, a semiconductor element, and a sealing resin. A dimension of a first exposed surface of the first lead is greater than a dimension of a first mounting surface of the first terminal. A dimension of a second exposed surface of the second lead is greater than a dimension of a second mounting surface of the second terminal. As viewed in a third direction that is the normal to the bottom surface of the sealing resin, a first end of the first exposed surface and a third end of the second exposed surface are positioned inward of a perimeter of the sealing resin. As viewed in the third direction, a fourth end of the second exposed surface overlaps with the perimeter of the sealing resin.

### FIELD

The present disclosure relates to semiconductor devices.

### BACKGROUND

As one type of semiconductor device package, a QFN is known, in which a plurality of leads are arranged on all four sides. JP-A-2020-77694 discloses an example of a semiconductor device having a QFN package. The semiconductor device includes a semiconductor element mounted on a plurality of leads, and the end surfaces of the leads are exposed so as to be flush with the side surfaces of the sealing resin (‘packaging material’ in JP-A-2020-77694). In addition, the back surfaces of the leads are exposed and flush with the bottom surface of the sealing resin. This semiconductor device is therefore more compact and occupies a smaller footprint on a wiring board, compared with a QFP having a plurality of leads protruding from the side surfaces of the sealing resin.

The semiconductor device disclosed in JP-A-2020-77694 is subject to thermal stress on the leads caused by heat generated from the semiconductor element. Owing to differences in shape and other factors, the magnitude of thermal stress acting on each lead may vary. As a result, a crack may form and propagate in the solder that electrically bonds the semiconductor device to a wiring board during use of the semiconductor device.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1, with a sealing resin shown as transparent.

FIG. 3 is a plan view corresponding to FIG. 2, with a semiconductor element additionally shown as transparent.

FIG. 4 is a bottom view of the semiconductor device shown in FIG. 1.

FIG. 5 is a front view of the semiconductor device shown in FIG. 1.

FIG. 6 is a rear view of the semiconductor device shown in FIG. 1.

FIG. 7 is a right-side view of the semiconductor device shown in FIG. 1.

FIG. 8 is a left-side view of the semiconductor device shown in FIG. 1.

FIG. 9 is a sectional view taken along line IX-IX in FIG. 3.

FIG. 10 is a sectional view taken along line X-X in FIG. 3.

FIG. 11 is a sectional view taken along line XI-XI in FIG. 3.

FIG. 12 is a sectional view taken along line XII-XII in FIG. 3.

FIG. 13 is a sectional view taken along line XIII-XIII in FIG. 3.

FIG. 14 is a plan view of a semiconductor device according to a variation of th first embodiment of the present disclosure, with a sealing resin and a semiconductor element shown as transparent.

FIG. 15 is a bottom view of the semiconductor device shown in FIG. 14.

FIG. 16 is a plan view of a semiconductor device according to a second embodiment of the present disclosure, with a sealing resin and a semiconductor element shown as transparent.

FIG. 17 is a bottom view of the semiconductor device shown in FIG. 16.

FIG. 18 is a plan view of a semiconductor device according to a third embodiment of t present disclosure, with a sealing resin and a semiconductor element shown as transparent.

FIG. 19 is a bottom view of the semiconductor device shown in FIG. 18.

FIG. 20 is a sectional view taken along line XX-XX in FIG. 18.

FIG. 21 is a sectional view taken along line XXI-XXI in FIG. 18.

FIG. 22 is a plan view of a semiconductor device according to a fourth embodiment the present disclosure, with a sealing resin and a semiconductor element shown as transparent.

FIG. 23 is a bottom view of the semiconductor device shown in FIG. 22.

FIG. 24 is a sectional view taken along line XXIV-XXIV in FIG. 22.

FIG. 25 is a plan view of a semiconductor device according to a fifth embodiment of th present disclosure, with a sealing resin and a semiconductor element shown as transparent.

FIG. 26 is a bottom view of the semiconductor device shown in FIG. 25.

FIG. 27 is a sectional view taken along line XXVII-XXVII in FIG. 25.

FIG. 28 is a plan view of a semiconductor device according to a variation of the fifth embodiment of the present disclosure, with a sealing resin and a semiconductor element shown as transparent.

FIG. 29 is a bottom view of the semiconductor device shown in FIG. 28.

FIG. 30 is a plan view of a semiconductor device according to a sixth embodiment of the present disclosure, with a sealing resin and a semiconductor element shown as transparent.

FIG. 31 is a bottom view of the semiconductor device shown in FIG. 30.

FIG. 32 is a sectional view taken along line XXXII-XXXII in FIG. 30.

### DETAILED DESCRIPTION

The following describes the present disclosure in detail with reference to the accompanying drawings.

### First Embodiment

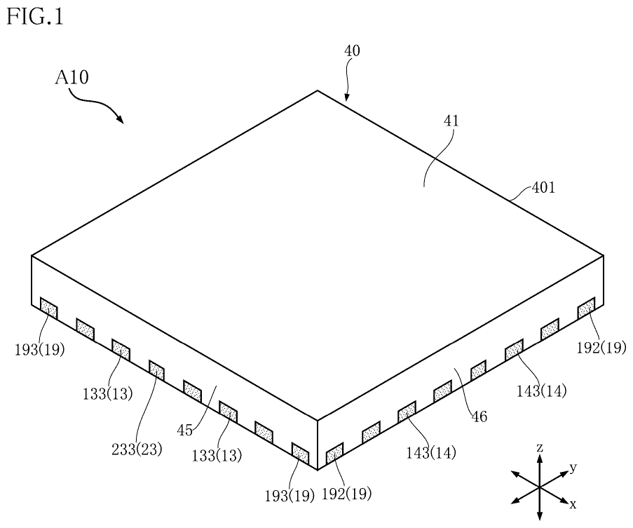

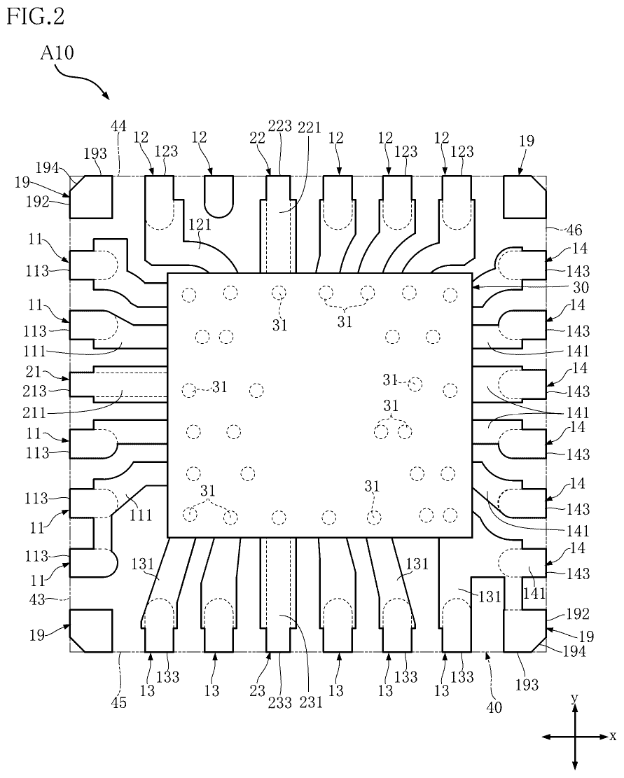

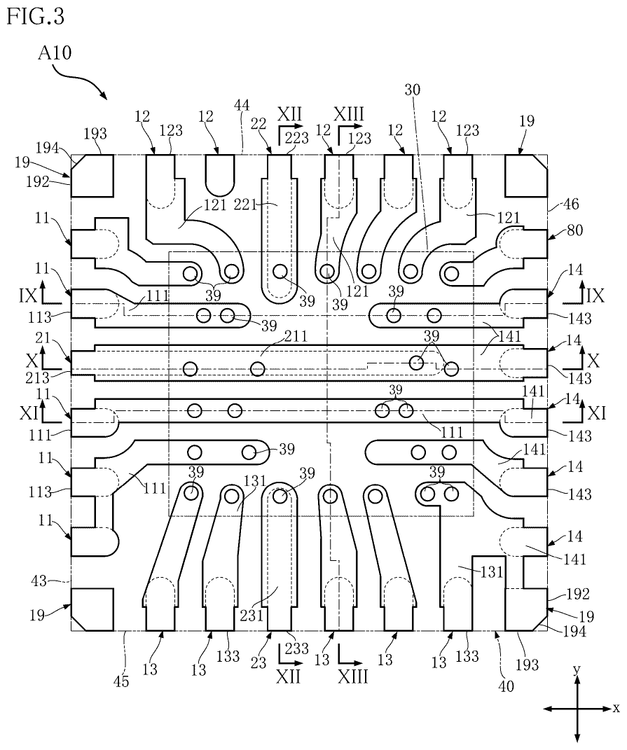

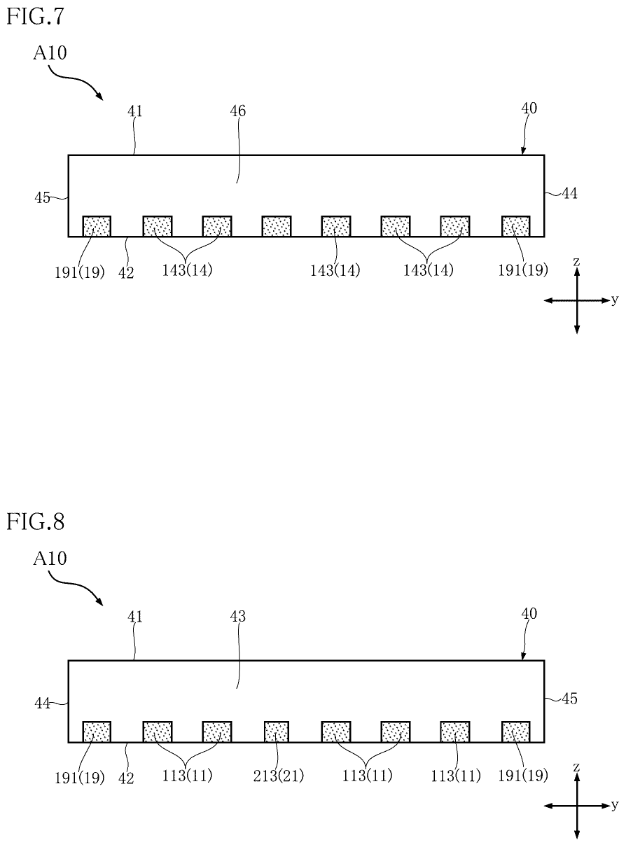

With reference to FIGS. 1 to 13, a semiconductor device A10 according to a first embodiment of the present disclosure will be described. The semiconductor device A10 includes a plurality of first terminals 11, a plurality of second terminals 12, a plurality of third terminals 13, a plurality of fourth terminals 14, a plurality of dummy terminals 19, a first lead 21, a second lead 22, a third lead 23, a semiconductor element 30, and a sealing resin 40. The package type of the semiconductor device A10 is QFN (Quad Flat No-Lead package). For ease of understanding, FIGS. 2 and 3 show the sealing resin 40 as transparent. For ease of understanding, FIG. 3 additionally shows the semiconductor element 30 as transparent. In FIGS. 2 and 3, the outline of the sealing resin 40 is shown by a phantom line (dash-double-dot line). In FIG. 3, the outline of the semiconductor element 30 is shown by a phantom line.

In the description of the semiconductor device A10, a direction along which the second terminals 12 are arranged is designated as the “first direction x”. A direction perpendicular to the first direction x is designated as “second direction y”. The direction perpendicular to both the first direction x and the second direction y is designated as “third direction z”. The third direction z corresponds to the direction of the normal to a top surface 41 and a bottom surface 42 of the sealing resin 40, which will be described later.

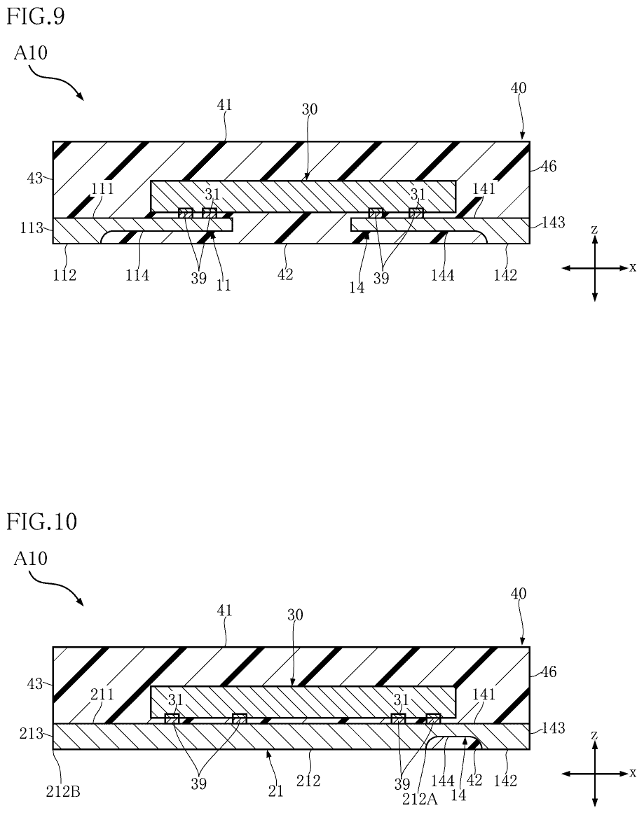

As shown in FIGS. 9, 11, and 13, the sealing resin 40 covers a portion of each terminal 11, a portion of each second terminal 12, a portion of each third terminal 13, and a portion of each fourth terminal 14. As shown in FIGS. 10 and 12, the sealing resin 40 also covers a portion of each of the first lead 21, the second lead 22, and the third lead 23, and the semiconductor element 30. The sealing resin 40 is electrically insulating. The sealing resin 40 is made of a black epoxy resin, for example. As viewed in the third direction z, the sealing resin 40 is rectangular.

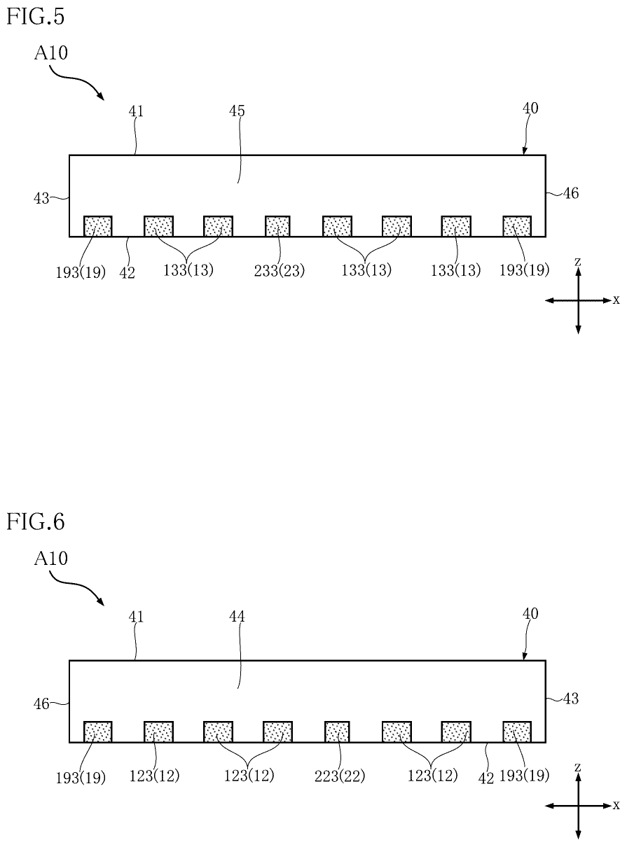

As shown in FIGS. 5 to 8, the sealing resin 40 has the top surface 41, the bottom surface 42, a first side surface 43, a second side surface 44, a third side surface 45, and a fourth side surface 46. The top surface 41 faces a first side in the third direction z. As shown in FIG. 1, the top surface 41 includes a perimeter 401 of the sealing resin 40. The bottom surface 42 faces away from the top surface 41 in the third direction z. The first side surface 43 faces a first side in the first direction x. The second side surface 44 faces a first side in the second direction y. The third side surface 45 faces away from the second side surface 44 in the second direction y. The fourth side surface 46 faces away from the first side surface 43 in the first direction x.

As shown in FIGS. 9 to 13, the semiconductor element 30 is supported on the first terminals 11, the second terminals 12, the third terminals 13, the fourth terminals 14, the first lead 21, the second lead 22, and the third lead 23. When the semiconductor device A10 is mounted on a wiring board, these terminals and leads form a conductive path between the semiconductor element 30 and the wiring board. These terminals and leads contain copper (Cu). These terminals and leads are formed from a single lead frame.

As shown in FIGS. 2 and 3, the first terminals 11 are positioned on the first in the first direction x. The first terminals 11 are arranged along the second direction y. In the semiconductor device A10, two first terminals 11 adjacent to each other in the second direction y among the first terminals 11 are connected to each other.

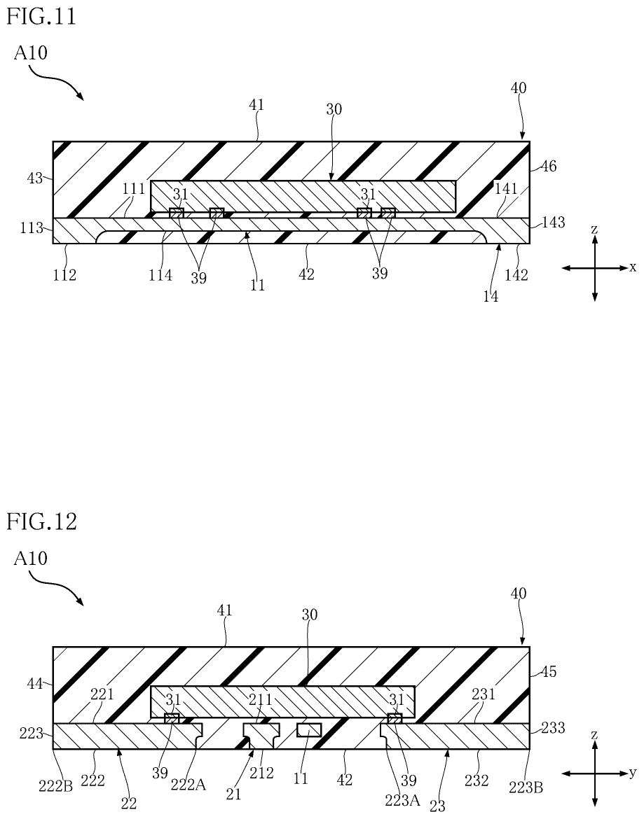

As shown in FIGS. 9 and 11, each first terminal 11 has a first supporting surface 111, a first mounting surface 112, a first end surface 113, and a first intermediate surface 114. The first supporting surface 111 faces the same side as the top surface 41 of the sealing resin 40 in the third direction z. The first supporting surface 111 faces the semiconductor element 30. The first mounting surface 112 faces away from the first supporting surface 111 in the third direction z. The first mounting surface 112 is exposed from the bottom surface 42 of the sealing resin 40. The first end surface 113 faces the first side in the first direction x. The first end surface 113 is exposed from the first side surface 43 of the sealing resin 40. The first intermediate surface 114 is positioned between the first supporting surface 111 and the first mounting surface 112 in the third direction z. As viewed in the third direction z, the first intermediate surface 114 overlaps with the first supporting surface 111. The first intermediate surface 114 is covered with the sealing resin 40.

As shown in FIGS. 2 and 3, the second terminals 12 are positioned on the first side in the second direction y. The second terminals 12 are arranged along the first direction x.

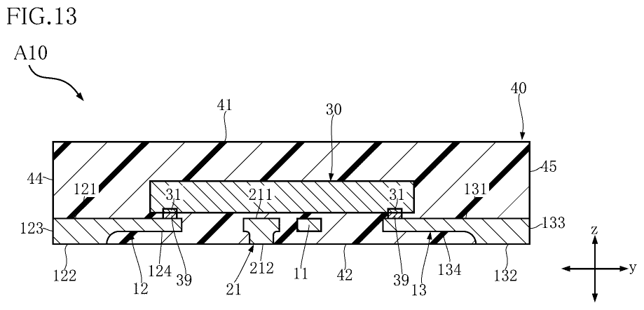

As shown in FIG. 13, each second terminal 12 has a second supporting surface 121, a second mounting surface 122, a second end surface 123, and a second intermediate surface 124. The second supporting surface 121 faces the same side as the top surface 41 of the sealing resin 40 in the third direction z. The second supporting surface 121 faces the semiconductor element 30. The second mounting surface 122 faces away from the second supporting surface 121 in the third direction z. The second mounting surface 122 is exposed from the bottom surface 42 of the sealing resin 40. The second end surface 123 faces the first side in the second direction y. The second end surface 123 is exposed from the second side surface 44 of the sealing resin 40. The second intermediate surface 124 is positioned between the second supporting surface 121 and the second mounting surface 122 in the third direction z. As viewed in the third direction z, the second intermediate surface 124 overlaps with the second supporting surface 121. The second intermediate surface 124 is covered with the sealing resin 40.

As shown in FIGS. 2 and 3, the third terminals 13 are positioned on the side opposite the second terminals 12 relative to the semiconductor element 30 in the second direction y. The third terminals 13 are arranged along the first direction x.

As shown in FIG. 13, each third terminal 13 has a third supporting surface 131, a third mounting surface 132, a third end surface 133, and a third intermediate surface 134. The third supporting surface 131 faces the same side as the top surface 41 of the sealing resin 40 in the third direction z. The third supporting surface 131 faces the semiconductor element 30. The third mounting surface 132 faces away from the third supporting surface 131 in the third direction z. The third mounting surface 132 is exposed from the bottom surface 42 of the sealing resin 40. The third end surface 133 faces away from the second end surface 123 of each second terminal 12 in the second direction y. The third end surface 133 is exposed from the third side surface 45 of the sealing resin 40. The third intermediate surface 134 is positioned between the third supporting surface 131 and the third mounting surface 132 in the third direction z. As viewed in the third direction z, the third intermediate surface 134 overlaps with the third supporting surface 131. The third intermediate surface 134 is covered with the sealing resin 40.

As shown in FIGS. 2 and 3, the fourth terminals 14 are positioned on the side opposite the first terminals 11 relative to the semiconductor element 30 in the first direction x. The fourth terminals 14 are arranged along the second direction y. In the semiconductor device A10, one of the fourth terminals 14 is connected to one of the first terminals 11. Additionally, one of the fourth terminals 14 is connected to one of the third terminals 13.

As shown in FIGS. 9 and 11, each fourth terminal 14 has a fourth supporting surface 141, a fourth mounting surface 142, a fourth end surface 143, and a fourth intermediate surface 144. The fourth supporting surface 141 faces the same side as the top surface 41 of the sealing resin 40 in the third direction z. The fourth supporting surface 141 faces the semiconductor element 30. The fourth mounting surface 142 faces away from the fourth supporting surface 141 in the third direction z. The fourth mounting surface 142 is exposed from the bottom surface 42 of the sealing resin 40. The fourth end surface 143 faces away from the first end surface 113 of each first terminal 11 in the first direction x. The fourth end surface 143 is exposed from the fourth side surface 46 of the sealing resin 40. The fourth intermediate surface 144 is positioned between the fourth supporting surface 141 and the fourth mounting surface 142 in the third direction z. As viewed in the third direction z, the fourth intermediate surface 144 overlaps with the fourth supporting surface 141. The fourth intermediate surface 144 is covered with the sealing resin 40.

As shown in FIGS. 2 to 4, the first lead 21 is positioned next to one of the first terminals 11 in the second direction y. The first lead 21 extends in the first direction x. In the semiconductor device A10, the first lead 21 is connected to one of the fourth terminals 14. As shown in FIG. 10, the first lead 21 has a first obverse surface 211, a first exposed surface 212, and a first end surface 213. The first obverse surface 211 faces the same side as the top surface 41 of the sealing resin 40 in the third direction z. The first obverse surface 211 faces the semiconductor element 30. The first exposed surface 212 faces away from the first obverse surface 211 in the third direction z. The first exposed surface 212 is exposed from the bottom surface 42 of the sealing resin 40. The first end surface 213 faces the same side as the first end surface 113 of each first terminal 11 in the first direction x. The first end surface 213 is exposed from the first side surface 43 of the sealing resin 40.

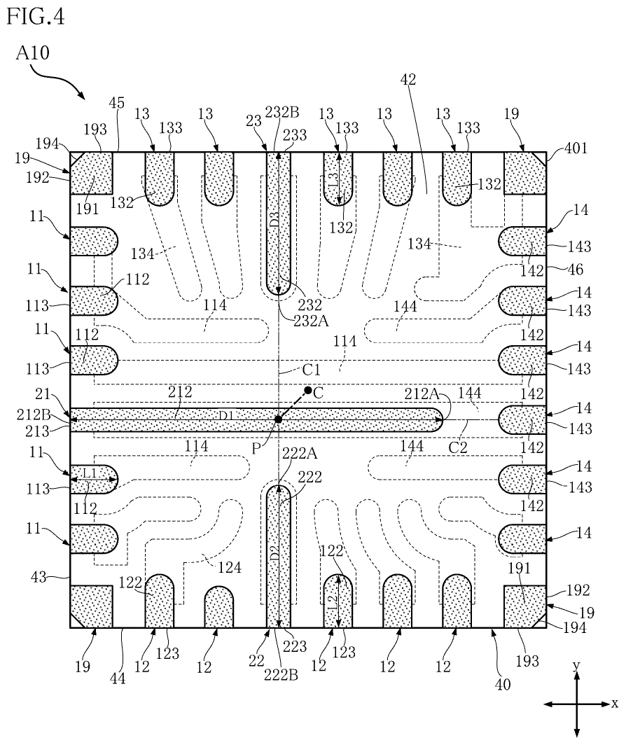

As shown in FIG. 4, the first exposed surface 212 of the first lead 21 has a dimension D1 in the first direction x, and the first mounting surface 112 of the first terminal 11 that is positioned next to the first lead 21 in the second direction y has a dimension L1 in the first direction x, where the dimension D1 is greater than the dimension L1. As shown in FIGS. 4 and 10, the first exposed surface 212 has a first end 212A and a second end 212B spaced apart from each other in the first direction x. As viewed in the third direction z, the first end 212A is positioned inward of the perimeter 401 of the sealing resin 40. As viewed in the third direction z, the second end 212B overlaps with the perimeter 401 of the sealing resin 40. The second end 212B is in contact with the bottom surface 42 of the sealing resin 40. Compared with the first end 212A, the second end 212B is positioned closer to the first mounting surface 112 of the first terminal 11 that is positioned next to the first lead 21 in the second direction y.

As shown in FIGS. 2 to 4, the second lead 22 is positioned next to one of the second terminals 12 in the first direction x. The second lead 22 extends in the second direction y. As shown in FIG. 12, the second lead 22 has a second obverse surface 221, a second exposed surface 222, and a second end surface 223. The second obverse surface 221 faces the same side as the top surface 41 of the sealing resin 40 in the third direction z. The second obverse surface 221 faces the semiconductor element 30. The second exposed surface 222 faces away from the second obverse surface 221 in the third direction z. The second exposed surface 222 is exposed from the bottom surface 42 of the sealing resin 40. The second end surface 223 faces the same side as the second end surface 123 of each second terminal 12 in the second direction y. The second end surface 223 is exposed from the second side surface 44 of the sealing resin 40.

As shown in FIG. 4, the second exposed surface 222 of the second lead 22 has a dimension D2 in the second direction y, and the second mounting surface 122 of the second terminal 12 that is positioned next to the second lead 22 in the first direction x has a dimension L2 in the second direction y, where the dimension D2 is greater than the dimension L2. As shown in FIGS. 4 and 12, the second exposed surface 222 has a third end 222A and a fourth end 222B that are spaced apart from each other in the second direction y. As viewed in the third direction z, the third end 222A is positioned inward of the perimeter 401 of the sealing resin 40. As viewed in the third direction z, the fourth end 222B overlaps with the perimeter 401 of the sealing resin 40. The fourth end 222B is in contact with the bottom surface 42 of the sealing resin 40. Compared with the third end 222A, the fourth end 222B is positioned closer to the second mounting surface 122 of the second terminal 12 that is positioned next to the second lead 22 in the first direction x.

As shown in FIGS. 2 to 4, the third lead 23 is positioned next to one of the third terminals 13 in the first direction x. The third lead 23 extends in the second direction y. As shown in FIG. 12, the third lead 23 has a third obverse surface 231, a third exposed surface 232, and a third end surface 233. The third obverse surface 231 faces the same side as the top surface 41 of the sealing resin 40 in the third direction z. The third obverse surface 231 faces the semiconductor element 30. The third exposed surface 232 faces away from the third obverse surface 231 in the third direction z. The third exposed surface 232 is exposed from the bottom surface 42 of the sealing resin 40. The third end surface 233 faces t he same side as the third end surface 133 of each third terminal 13 in the second direction y. The third end surface 233 is exposed from the third side surface 45 of the sealing resin 40.

As shown in FIG. 4, the third exposed surface 232 of the third lead 23 has a dimension D3 in the second direction y, and the third mounting surface 132 of the third terminal 13 that is positioned next to the third lead 23 in the first direction x has a dimension L3 in the second direction y, where the dimension D3 is greater than the dimension L3. As shown in FIGS. 4 and 12, the third exposed surface 232 has a fifth end 232A and a sixth end 232B that are spaced apart from each other in the second direction y. As viewed in the third direction z, the fifth end 232A is positioned inward of the perimeter 401 of the sealing resin 40. As viewed in the third direction z, the sixth end 232B overlaps with the perimeter 401 of the sealing resin 40. The sixth end 232B is in contact with the bottom surface 42 of the sealing resin 40. Compared with the fifth end 232A, the sixth end 232B is positioned closer to the third mounting surface 132 of the third terminal 13 that is positioned next to the third lead 23 in the first direction x.

As shown in FIG. 4, the dimension D1 of the first exposed surface 212 of the first lead 21 is greater than the dimension D2 of the second exposed surface 222 of the second lead 22. In the semiconductor device A10, the dimension D3 of the third exposed surface 232 of the third lead 23 is equal to the dimension D2 of the second exposed surface 222.

As shown in FIG. 4, the first exposed surface 212 of the first lead 21 and the th exposed surface 232 of the third lead 23 overlap with a first center line C1 in the third direction z. The first center line C1 is a straight line that extends in the second direction y and passes through the center of the second exposed surface 222 of the second lead 22 in the first direction x. The third end 222A of the second exposed surface 222 is positioned closer to the first exposed surface 212 than is the fifth end 232A of the third exposed surface 232.

FIG. 4 shows a second center line C2 and an intersection point P of the first center line C1 and the second center line C2. As viewed in the third direction z, the distance between the intersection point P and the center C of the bottom surface 42 of the sealing resin 40 is less than or equal to the dimension L1 of the first mounting surface 112 of the first terminal 11. The second center line C2 is a straight line that extends in the first direction x and passes through the center of the first exposed surface 212 of the first lead 21 in the second direction y. As viewed in the third direction z, the fourth mounting surface 142 of the fourth terminal 14 overlaps with the second center line C2.

As shown in FIGS. 2 to 4, the dummy terminals 19 are positioned at the four corners of the sealing resin 40 as viewed in the third direction z. At least one of the dummy terminals 19 is not electrically connected to the semiconductor element 30. In the semiconductor device A10, one of the dummy terminals 19 is connected to one of the fourth terminals 14. The dummy terminals 19 contain copper.

As shown in FIGS. 3 and 4, each dummy terminal 19 has a dummy exposed surface 191, a first surface 192, a second surface 193, and a third surface 194. The dummy exposed surface 191 faces away from the top surface 41 of the sealing resin 40 in the third direction z. The dummy exposed surface 191 is exposed from the bottom surface 42 of the sealing resin 40. The dimension of the dummy exposed surface 191 in the first direction x is greater than the dimension of the second mounting surface 122 of each second terminal 12 in the first direction x. The dimension of the dummy exposed surface 191 in the second direction y is greater than the dimension of the first mounting surface 112 of each first terminal 11 in the second direction y. The first surface 192 faces one side in the first direction x. The first surface 192 is exposed from the first side surface 43 or the fourth side surface 46 of the sealing resin 40. The second surface 193 faces one side in the second direction y. The second surface 193 is exposed from the second side surface 44 or the third side surface 45 of the sealing resin 40. The third surface 194 is connected to the first surface 192 and the second surface 193. The third surface 194 is inclined relative to both the first direction x and the second direction y. The third surface 194 is covered with the sealing resin 40.

As shown in FIGS. 9 to 13, the semiconductor element 30 is supported on the first terminals 11, the second terminals 12, the third terminals 13, the fourth terminals 14, the first lead 21, the second lead 22, and the third lead 23. The semiconductor element 30 is an LSI (large scale integration), for example. The semiconductor element 30 has a plurality of electrodes 31. The electrodes 31 are disposed on the side facing the first terminals 11, the second terminals 12, the third terminals 13, and the fourth terminals 14 in the third direction z. Each electrode 31 is electrically bonded to one of the first terminals 11, the second terminals 12, the third terminals 13, the fourth terminals 14, the first lead 21, the second lead 22, and the third lead 23 via a bonding layer 39. Consequently, the semiconductor element 30 is electrically connected to the first terminals 11, the second terminals 12, the third terminals 13, the fourth terminals 14, the first lead 21, the second lead 22, and the third lead 23. The bonding layer 39 contains nickel (Ni) and includes laminated layers of tin (Sn) and silver (Ag). In other examples, the bonding layer 39 may contain nickel, tin, and antimony (Sb).

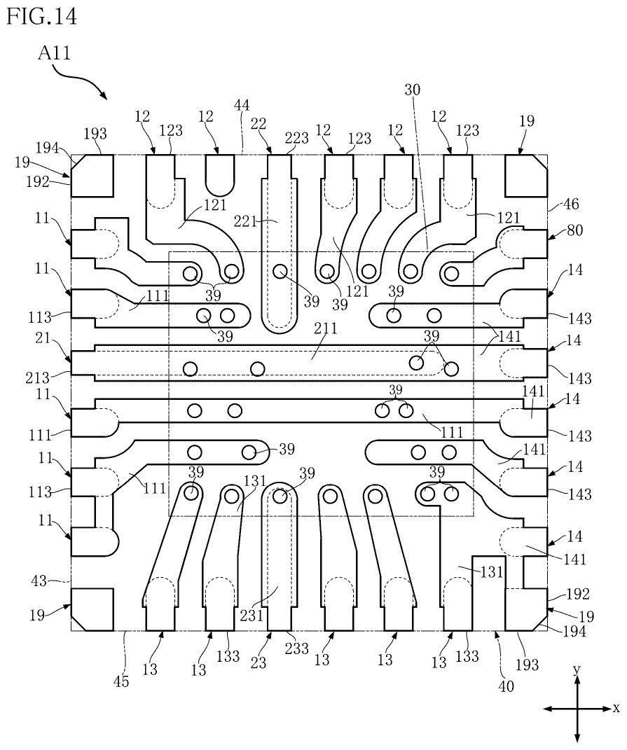

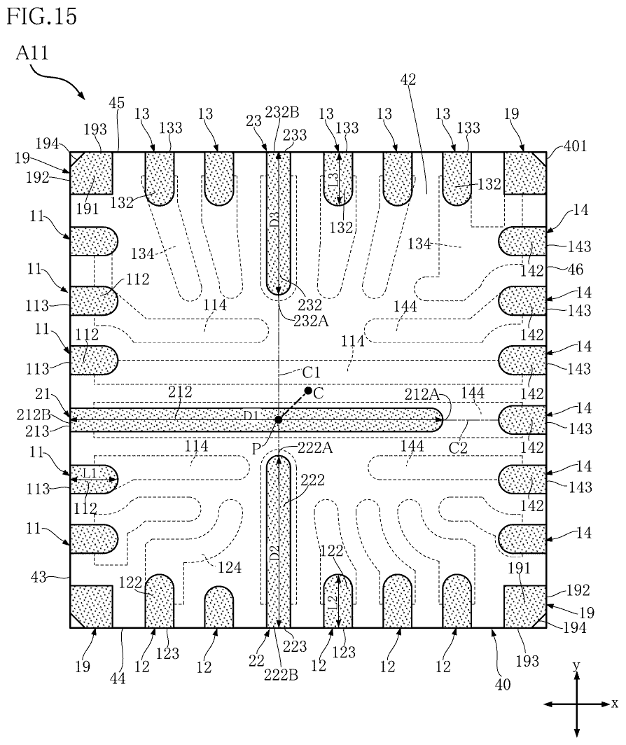

With reference to FIGS. 14 and 15, the following describes a semiconductor device A11 according to a variation of the first embodiment of the present disclosure. For ease of understanding, FIG. 14 shows the semiconductor element 30 and the sealing resin 40 as transparent. In FIG. 14, the outlines of the semiconductor element 30 and the sealing resin 40 are shown by phantom lines.

As shown in FIG. 15, the semiconductor device A11 differs from the semiconductor device A10 in that dimension D2 of the second exposed surface 222 of the second lead 22 is greater than the dimension D3 of the third exposed surface 232 of the third lead 23.

The following describes effects of the semiconductor device A10.

The semiconductor device A10 includes a first terminal 11, a second terminal 12, third terminal 13, a fourth terminal 14, a first lead 21, a second lead 22, a semiconductor element 30, and a sealing resin 40. The first lead 21 has a first exposed surface 212 with a dimension D1, and the first terminal 11 has a first mounting surface 112 with a dimension L1, where the dimension D1 is greater than the dimension L1. The second lead 22 has a second exposed surface 222 with a dimension D2, and the second terminal 12 has a second mounting surface 122 with a dimension L2, where the dimension D2 is greater than the dimension L2. As viewed in the third direction z, the first end 212A of the first exposed surface 212 and the third end 222A of the second exposed surface 222 are positioned inward of the perimeter 401 of the sealing resin 40. As viewed in the third direction z, the fourth end 222B of the second exposed surface 222 overlaps with the perimeter 401 of the sealing resin 40. This configuration reduces the thermal stress imbalance between the first terminal 11 and the second terminal 12 caused by heat generated by the semiconductor element 30. During operation of the semiconductor device A10, this serves to reduce or prevent cracking in the solder that electrically bonds the semiconductor device A10 to a wiring board. The semiconductor device A10 of this configuration ensures that the thermal stress on the plurality of terminals is more uniform.

The semiconductor device A10 additionally includes a third lead 23. The third lead 23 has a third exposed surface 232 with a dimension D3, and the third terminal 13 has a third mounting surface 132 with a dimension L3, where the dimension D3 is greater than the dimension L3. As viewed in the third direction z, the fifth end 232A of the third exposed surface 232 is positioned inward of the perimeter 401 of the sealing resin 40. As viewed in the third direction z, the sixth end 232B of the third exposed surface 232 overlaps with the perimeter 401 of the sealing resin 40. The configuration ensures that the thermal stress caused by heat generated by the semiconductor element 30 on the first terminal 11, the second terminal 12, and the third terminal 13 is more uniform.

The configuration described above satisfies that the distance from the intersection point P of the first center line C1 and the second center line C2 to the center C of the bottom surface 42 of the sealing resin 40 is less than the dimension L1 of the first mounting surface 112 of the first terminal 11 as viewed in the third direction z (see FIG. 4). This configuration more efficiently ensures that thermal stress on the first terminal 11, the second terminal 12, and the third terminal 13 is uniform.

The second end 212B of the first exposed surface 212 of the first lead 21, the fourth end 222B of the second exposed surface 222 of the second lead 22, and the sixth end 232B of the third exposed surface 232 of the third lead 23 are in contact with the bottom surface 42 of the sealing resin 40. This configuration reduces thermal stress concentration on the first lead 21, the second lead 22, and the third lead 23.

The sealing resin 40 has a first side surface 43 that faces one side in the first direction x. The first terminal 11 and the first lead 21 are exposed from the first side surface 43. This configuration facilitates a greater volume of solder adhering the first terminal 11 and the first lead 21 during mounting of the semiconductor device A10 to a wiring board. This consequently increases the bonding strength of the semiconductor device A10 to the wiring board.

The sealing resin 40 has a second side surface 44 that faces one side in the second direction y. The second terminal 12 and the second lead 22 are exposed from the second side surface 44. This configuration facilitates a greater volume of solder adhering the second terminal 12 and the second lead 22 during mounting of the semiconductor device A10 to a wiring board. This consequently increases the bonding strength of the semiconductor device A10 to the wiring board.

The semiconductor device A10 additionally includes a plurality of dummy terminals 19 at the four corners of the sealing resin 40 as viewed in the third direction z. Each dummy terminal 19 has a dummy exposed surface 191 exposed from the bottom surface 42 of the sealing resin 40. When the semiconductor device A10 is mounted to a wiring board, the dummy exposed surfaces 191 of the dummy terminals 19 are bonded to the wiring board. This serves to reduce thermal stress concentration on the first terminal 11, the second terminal 12, the third terminal 13, and the fourth terminal 14.

In the case described above, each dummy exposed surface 191 has a greater dimension in the first direction x than the dimension of the second mounting surface 122 of the second terminal 12 in the first direction x. Also, each dummy exposed surface 191 has a greater dimension in the second direction y than the dimension of the first terminal 11 in the second direction y. This configuration more efficiently reduces thermal stress concentration on the first terminal 11, the second terminal 12, the third terminal 13, and the fourth terminal 14.

### Second Embodiment

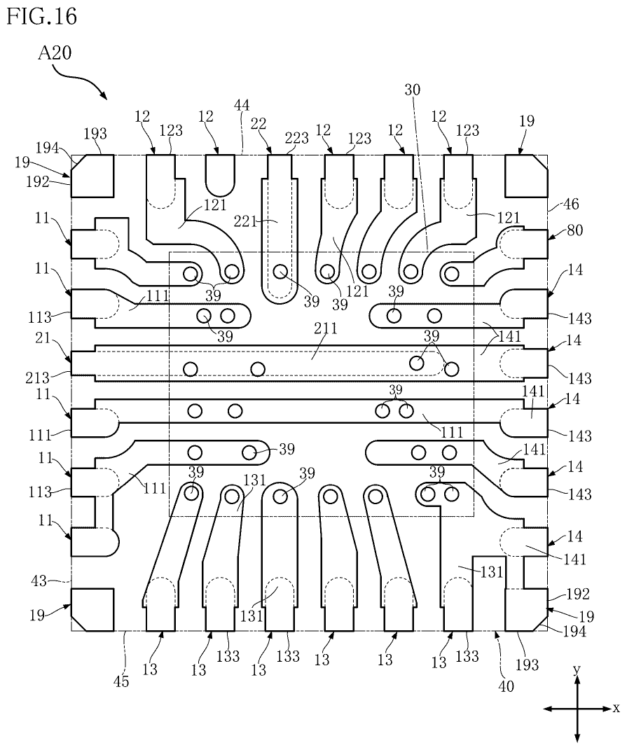

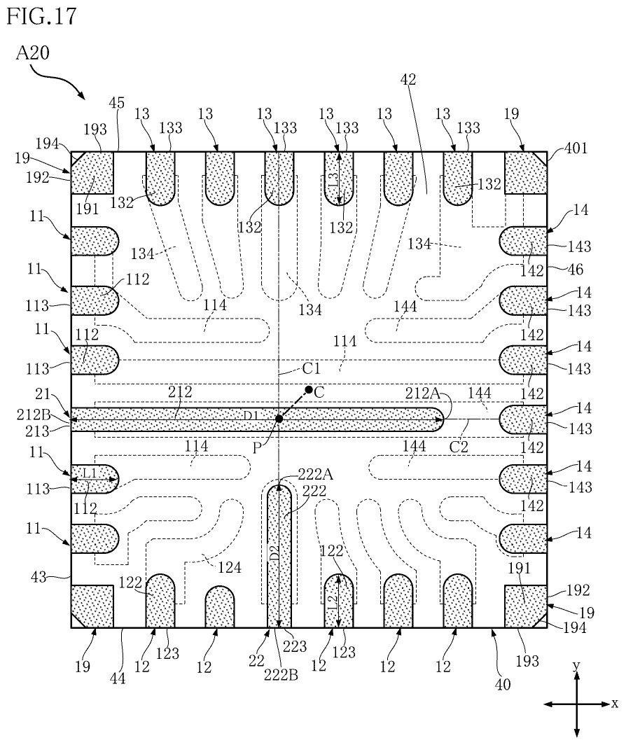

With reference to FIGS. 16 and 17, the following describes a semiconductor device A20 according to a second embodiment of the present disclosure. In these figures, elements that are identical or similar to those of the semiconductor device A10 described above are indicated by the same reference numerals, and redundant descriptions are omitted. For ease of understanding, FIG. 16 shows the semiconductor element 30 and the sealing resin 40 as transparent. In FIG. 16, the outlines of the semiconductor element 30 and the sealing resin 40 are shown by phantom lines.

The semiconductor device A20 differs from the semiconductor device A10 in the absence of the third lead 23.

As shown in FIGS. 16 and 17, the semiconductor device A20 lacks the third lead 23. In the semiconductor device A20, the third lead 23 is replaced by the third terminal 13.

The following describes effects of the semiconductor device A20.

The semiconductor device A20 includes a first terminal 11, a second terminal 12, third terminal 13, a fourth terminal 14, a first lead 21, a second lead 22, a semiconductor element 30, and a sealing resin 40. The first lead 21 has a first exposed surface 212 with a dimension D1, and the first terminal 11 has a first mounting surface 112 with a dimension L1, where the dimension D1 is greater than the dimension L1. The second lead 22 has a second exposed surface 222 with a dimension D2, and the second terminal 12 has a second mounting surface 122 with a dimension L2, where the dimension D2 is greater than the dimension L2. As viewed in the third direction z, the first end 212A of the first exposed surface 212 and the third end 222A of the second exposed surface 222 are positioned inward of the perimeter 401 of the sealing resin 40. As viewed in the third direction z, the fourth end 222B of the second exposed surface 222 overlaps with the perimeter 401 of the sealing resin 40. The semiconductor device A20 of this configuration ensures that the thermal stress on the plurality of terminals is more uniform. Additionally, the semiconductor device A20 has a configuration in common with the semiconductor device A10, thereby achieving the same effect as the semiconductor device A10.

### Third Embodiment

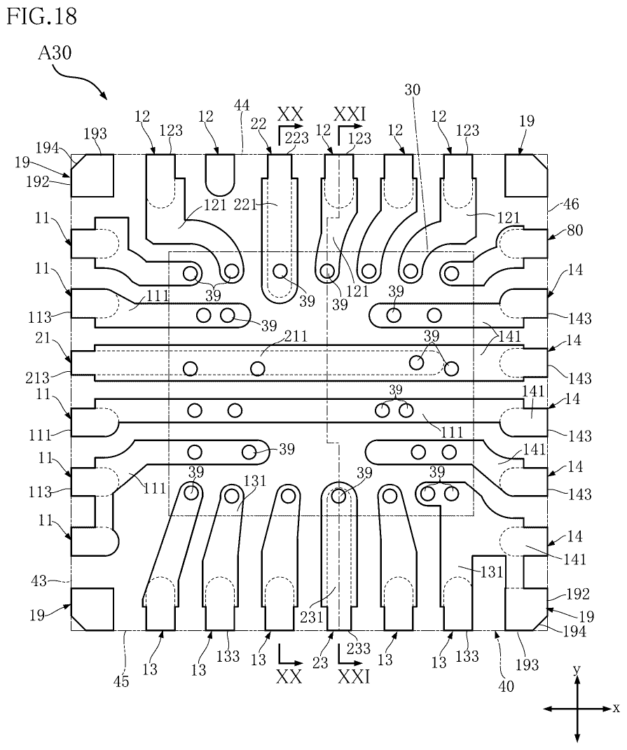

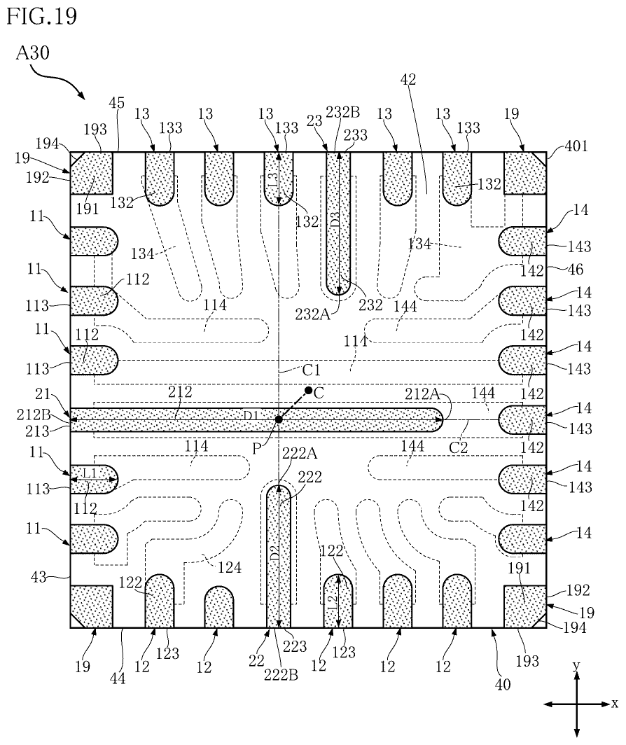

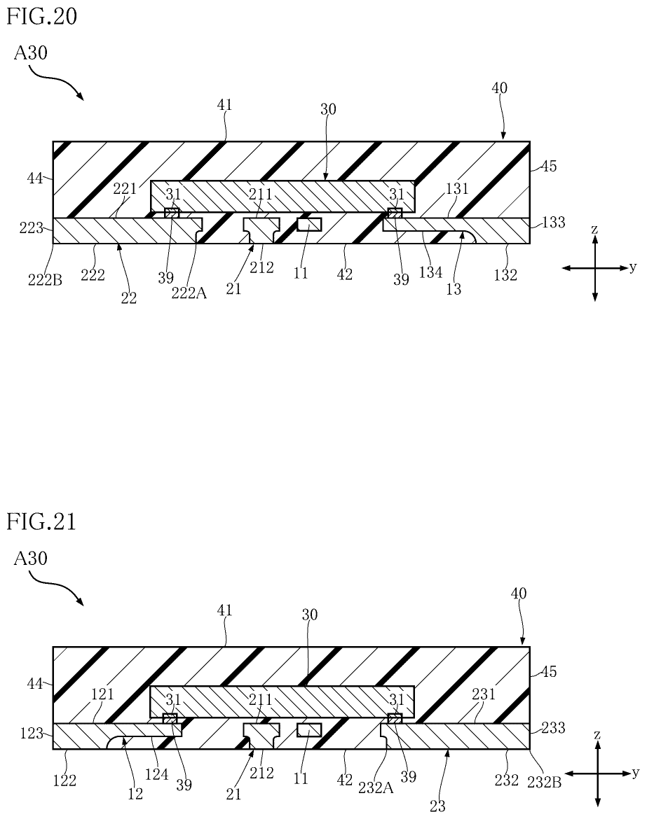

With reference to FIGS. 18 to 21, the following describes a semiconductor device A according to a third embodiment of the present disclosure. In these figures, elements that are identical or similar to those of the semiconductor device A10 described above are indicated by the same reference numerals, and redundant descriptions are omitted. For ease of understanding, FIG. 18 shows the semiconductor element 30 and the sealing resin 40 as transparent. In FIG. 18, the outlines of the semiconductor element 30 and the sealing resin 40 are shown by phantom lines.

The semiconductor device A30 differs from the semiconductor device A10 in the configurations of the second lead 22 and the third lead 23.

As shown in FIGS. 18 to 21, the third lead 23 is positioned differently from that in the semiconductor device A10. As viewed in the third direction z, the third exposed surface 232 of the third lead 23 is offset from the first center line C1.

The following describes effects of the semiconductor device A30.

The semiconductor device A30 includes a first terminal 11, a second terminal 12, a third terminal 13, a fourth terminal 14, a first lead 21, a second lead 22, a semiconductor element 30, and a sealing resin 40. The first lead 21 has a first exposed surface 212 with a dimension D1, and the first terminal 11 has a first mounting surface 112 with a dimension L1, where the dimension D1 is greater than the dimension L1. The second lead 22 has a second exposed surface 222 with a dimension D2, and the second terminal 12 has a second mounting surface 122 with a dimension L2, where the dimension D2 is greater than the dimension L2. As viewed in the third direction z, the first end 212A of the first exposed surface 212 and the third end 222A of the second exposed surface 222 are positioned inward of the perimeter 401 of the sealing resin 40. As viewed in the third direction z, the fourth end 222B of the second exposed surface 222 overlaps with the perimeter 401 of the sealing resin 40. The semiconductor device A30 of this configuration ensures that the thermal stress on the plurality of terminals is more uniform. Additionally, the semiconductor device A30 has a configuration in common with the semiconductor device A10, thereby achieving the same effect as the semiconductor device A10.

### Fourth Embodiment

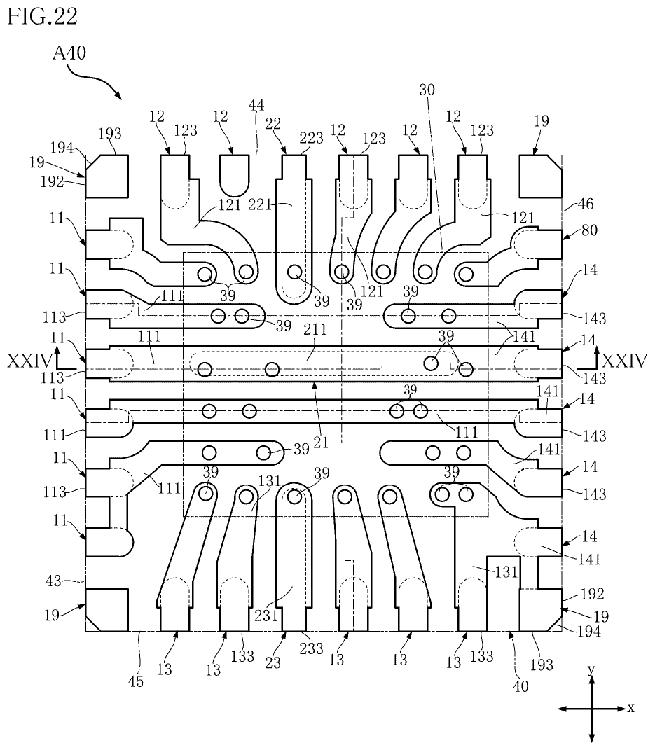

With reference to FIGS. 22 to 24, the following describes a semiconductor device A40 according to a fourth embodiment of the present disclosure. In these figures, elements that are identical or similar to those of the semiconductor device A10 described above are indicated by the same reference numerals, and redundant descriptions are omitted. For ease of understanding, FIG. 22 shows the semiconductor element 30 and the sealing resin 40 as transparent. In FIG. 22, the outlines of the semiconductor element 30 and the sealing resin 40 are shown by phantom lines.

The semiconductor device A40 differs from the semiconductor device A10 in the configuration of the first lead 21.

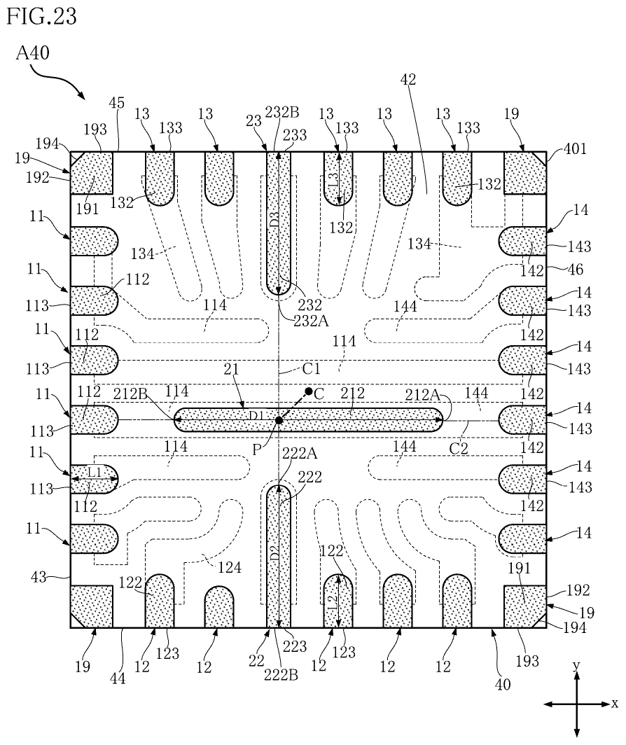

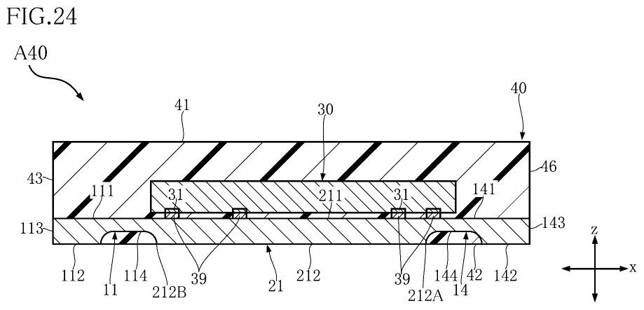

As shown in FIGS. 23 and 24, the second end 212B of the first exposed surface 212 of the first lead 21 is positioned inward of the perimeter 401 of the sealing resin 40. The dimension D1 of the first exposed surface 212 is less than that in the semiconductor device A10. As viewed in the third direction z, the first exposed surface 212 overlaps with the first center line C1.

The following describes effects of the semiconductor device A40.

The semiconductor device A40 includes a first terminal 11, a second terminal 12, a third terminal 13, a fourth terminal 14, a first lead 21, a second lead 22, a semiconductor element 30, and a sealing resin 40. The first lead 21 has a first exposed surface 212 with a dimension D1, and the first terminal 11 has a first mounting surface 112 with a dimension L1, where the dimension D1 is greater than the dimension L1. The second lead 22 has a second exposed surface 222 with a dimension D2, and the second terminal 12 has a second mounting surface 122 with a dimension L2, where the dimension D2 is greater than the dimension L2. As viewed in the third direction z, the first end 212A of the first exposed surface 212 and the third end 222A of the second exposed surface 222 are positioned inward of the perimeter 401 of the sealing resin 40. As viewed in the third direction z, the fourth end 222B of the second exposed surface 222 overlaps with the perimeter 401 of the sealing resin 40. The semiconductor device A40 of this configuration ensures that the thermal stress on the plurality of terminals is more uniform. Additionally, the semiconductor device A40 has a configuration in common with the semiconductor device A10, thereby achieving the same effect as the semiconductor device A10.

### Fifth Embodiment

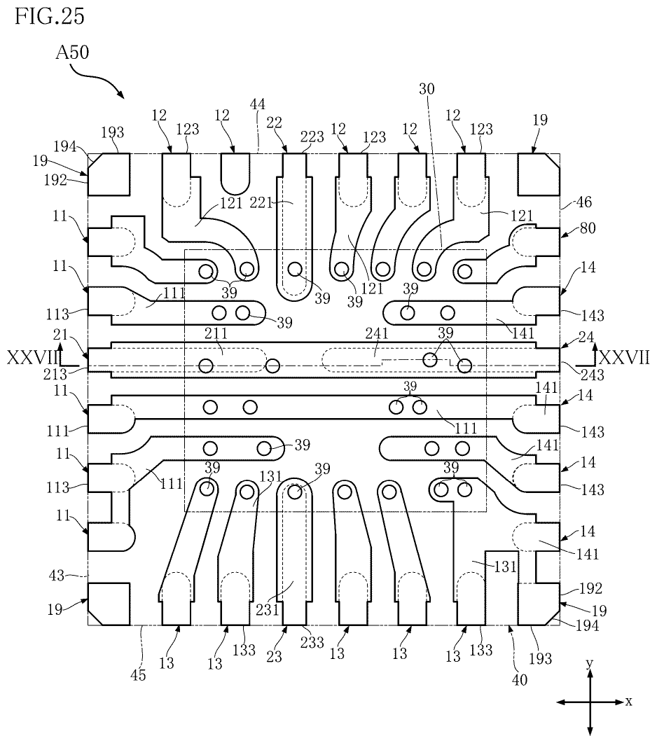

With reference to FIGS. 25 to 27, the following describes a semiconductor device A50 according to a fifth embodiment of the present disclosure. In these figures, elements that are identical or similar to those of the semiconductor device A10 described above are indicated by the same reference numerals, and redundant descriptions are omitted. For ease of understanding, FIG. 25 shows the semiconductor element 30 and the sealing resin 40 as transparent. In FIG. 25, the outlines of the semiconductor element 30 and the sealing resin 40 are shown by phantom lines.

The semiconductor device A50 differs from the semiconductor device A10 in that i additionally includes a fourth lead 24.

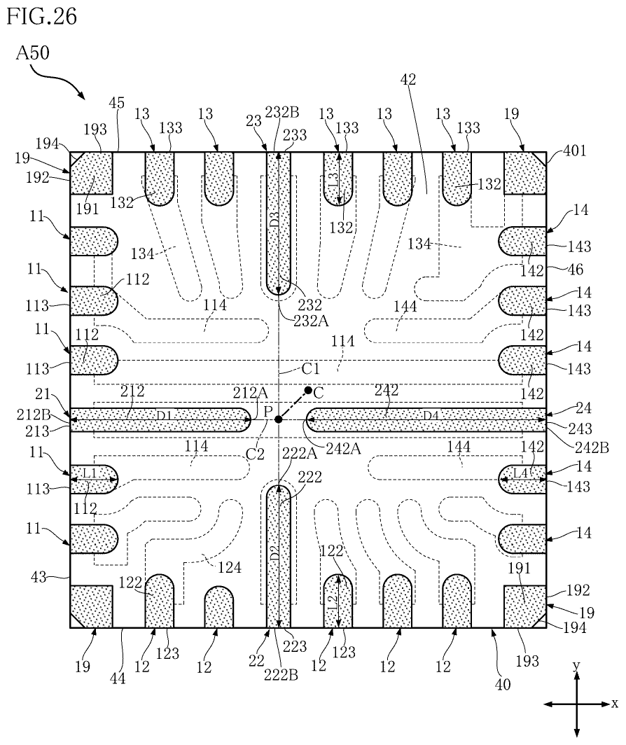

As shown in FIGS. 25 and 26, the fourth lead 24 is positioned next to one of the fourth terminals 14 in the second direction y. The fourth lead 24 extends in the first direction x. In the semiconductor device A50, the fourth lead 24 is connected to the first lead 21. Thus, the fourth lead 24 is electrically connected to the semiconductor element 30 via the first lead 21. The fourth lead 24 has a fourth obverse surface 241, a fourth exposed surface 242, and a fourth end surface 243. The fourth obverse surface 241 faces the same side as the top surface 41 of the sealing resin 40 in the third direction z. The fourth obverse surface 241 faces the semiconductor element 30. The fourth exposed surface 242 faces away from the fourth obverse surface 241 in the third direction z. The fourth exposed surface 242 is exposed from the bottom surface 42 of the sealing resin 40. The fourth end surface 243 faces the same side as the fourth end surface 143 of each fourth terminal 14 in the first direction x. The fourth end surface 243 is exposed from the fourth side surface 46 of the sealing resin 40.

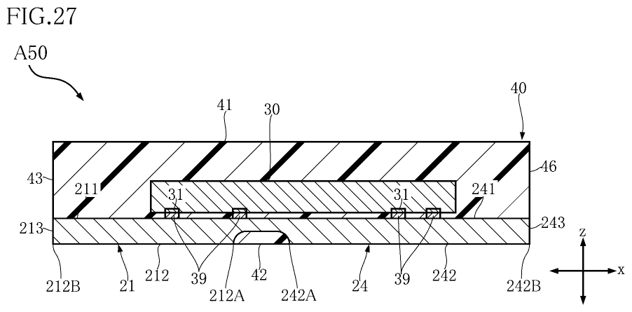

As shown in FIG. 26, the fourth exposed surface 242 of the fourth lead 24 has a dimension D4 in the first direction x, and the fourth mounting surface 142 of the fourth terminal 14 that is positioned next to the fourth lead 24 in the second direction y has a dimension L4 in the first direction x, where the dimension D4 is greater than the dimension L4. As shown in FIGS. 26 and 27, the fourth exposed surface 242 has a seventh end 242A and an eighth end 242B that are spaced apart in the first direction x. As viewed in the third direction z, the seventh end 242A is positioned inward of the perimeter 401 of the sealing resin 40. As viewed in the third direction z, the eighth end 242B overlaps with the perimeter 401 of the sealing resin 40. The eighth end 242B is in contact with the bottom surface 42 of the sealing resin 40. Compared with the seventh end 242A, the eighth end 242B is positioned closer to the fourth mounting surface 142 of the fourth terminal 14 that is positioned next to the fourth lead 24 in the second direction y.

As shown in FIG. 26, as viewed in the third direction z, the first exposed surface of the first lead 21 and the fourth exposed surface 242 of the fourth lead 24 are both offset from the first center line C1. As viewed in the third direction z, the fourth exposed surface 242 overlaps with the second center line C2, and the second exposed surface 222 of the second lead 22 and the third exposed surface 232 of the third lead 23 are offset from the second center line C2. The dimension D4 of the fourth exposed surface 242 differs from the dimension D1 of the first exposed surface 212 of the first lead 21. In the semiconductor device A50, the dimension D4 of the fourth exposed surface 242 is greater than the dimension D1 of the first exposed surface 212.

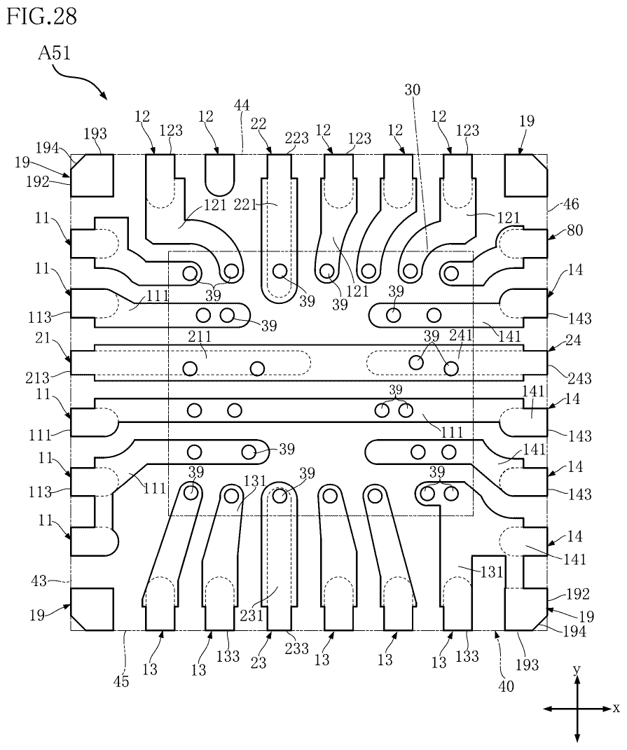

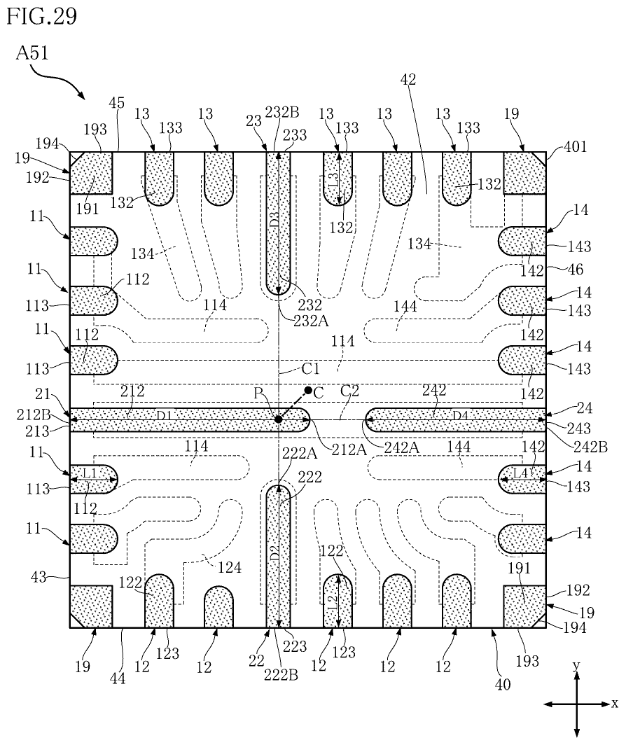

With reference to FIGS. 28 and 29, the following describes a semiconductor device A according to a variation of the fifth embodiment of the present disclosure. For ease of understanding, FIG. 28 shows the semiconductor element 30 and the sealing resin 40 as transparent. In FIG. 28, the outlines of the semiconductor element 30 and the sealing resin 40 are shown by phantom lines.

As shown in FIG. 29, the semiconductor device A51 is configured such that, as viewed in the third direction z, the first exposed surface 212 of the first lead 21 overlaps with the first center line C1, and the fourth exposed surface 242 of the fourth lead 24 is offset from the first center line C1. In the semiconductor device A51, the dimension D4 of the fourth exposed surface 242 is less than the dimension D1 of the first exposed surface 212.

The following describes effects of the semiconductor device A50.

The semiconductor device A50 includes a first terminal 11, a second terminal 12, a third terminal 13, a fourth terminal 14, a first lead 21, a second lead 22, a semiconductor element 30, and a sealing resin 40. The first lead 21 has a first exposed surface 212 with a dimension D1, and the first terminal 11 has a first mounting surface 112 with a dimension L1, where the dimension D1 is greater than the dimension L1. The second lead 22 has a second exposed surface 222 with a dimension D2, and the second terminal 12 has a second mounting surface 122 with a dimension L2, where the dimension D2 is greater than the dimension L2. As viewed in the third direction z, the first end 212A of the first exposed surface 212 and the third end 222A of the second exposed surface 222 are positioned inward of the perimeter 401 of the sealing resin 40. As viewed in the third direction z. the fourth end 222B of the second exposed surface 222 overlaps with the perimeter 401 of the sealing resin 40. The semiconductor device A50 of this configuration ensures that the thermal stress on the plurality of terminals is more uniform. Additionally, the semiconductor device A50 has a configuration in common with the semiconductor device A10, thereby achieving the same effect as the semiconductor device A10.

The semiconductor device A50 additionally includes a fourth lead 24. The fourth lead 24 has a fourth exposed surface 242 with a dimension D4, and the fourth terminal 14 has a fourth mounting surface 142 with a dimension L4, where the dimension D4 is greater than the dimension L4. As viewed in the third direction z, the seventh end 242A of the fourth exposed surface 242 is positioned inward of the perimeter 401 of the sealing resin 40. As viewed in the third direction z, the eighth end 242B of the fourth exposed surface 242 overlaps with the perimeter 401 of the sealing resin 40. The configuration ensures that the thermal stress caused by heat generated by the semiconductor element 30 on the first terminal 11, the second terminal 12, the third terminal 13, and the fourth terminal 14 is more uniform.

### Sixth Embodiment

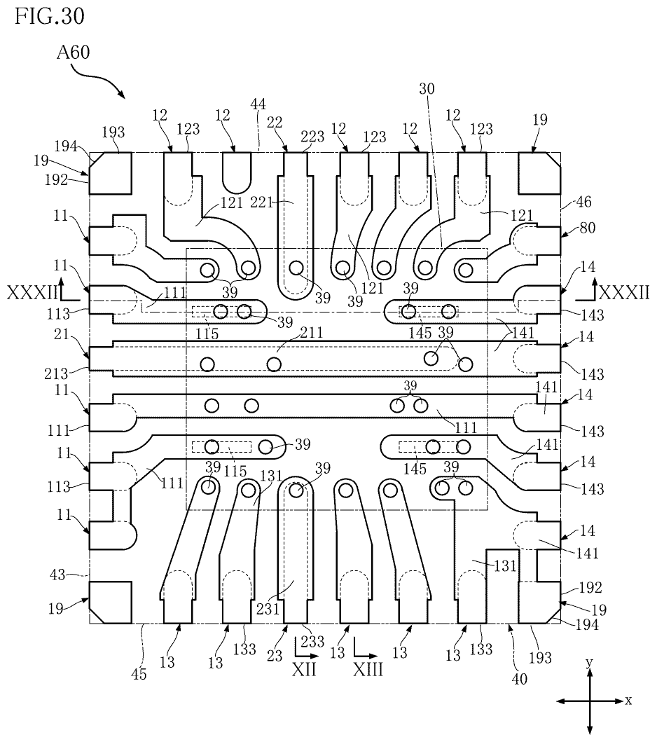

With reference to FIGS. 30 to 32, the following describes a semiconductor device A60 according to a sixth embodiment of the present disclosure. In these figures, elements that are identical or similar to those of the semiconductor device A10 described above are indicated by the same reference numerals, and redundant descriptions are omitted. For ease of understanding, FIG. 30 shows the semiconductor element 30 and the sealing resin 40 as transparent. In FIG. 30, the outlines of the semiconductor element 30 and the sealing resin 40 are shown by phantom lines.

The semiconductor device A60 differs from the semiconductor device A10 in the configurations of the first terminals 11 and the fourth terminals 14.

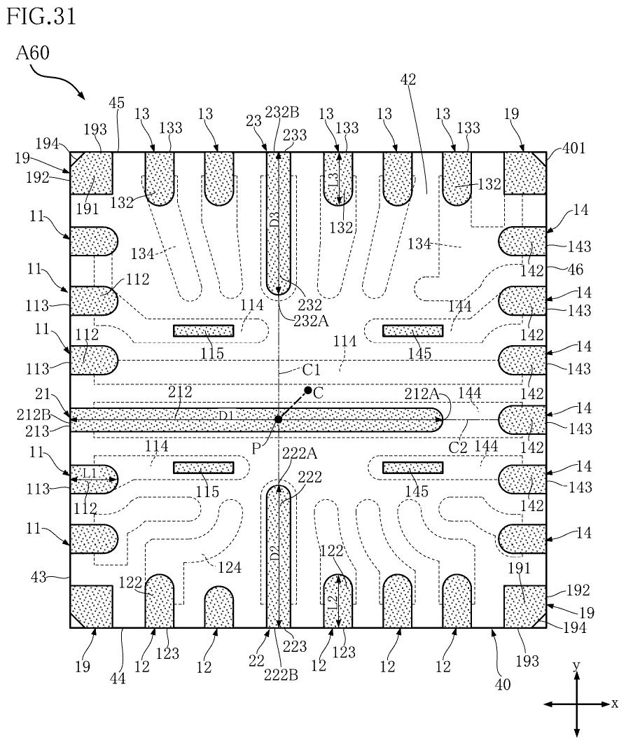

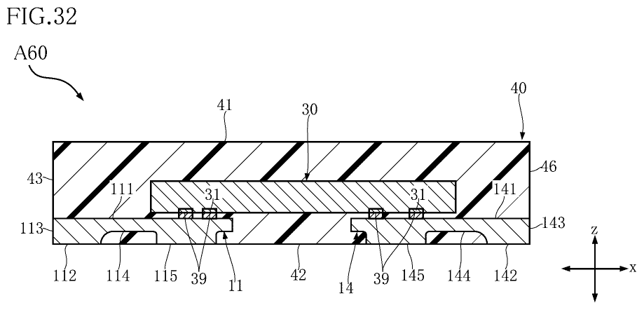

As shown in FIGS. 31 and 32, the first terminals 11 include two first terminals each of which has a first sub-mounting surface 115. The first sub-mounting surface 115 is exposed from the bottom surface 42 of the sealing resin 40. Each of the two first terminals 11 is configured such that, on the bottom surface 42 of the sealing resin 40. the first sub-mounting surface 115 is positioned farther inward than the first mounting surface 112. For each of the two first terminals 11, the dimension of the first sub-mounting surface 115 in the second direction y is less than the dimension of the first mounting surface 112 in the second direction y. For each of the two first terminals 11, the first sub-mounting surface 115 is positioned closer to the first exposed surface 212 of the first lead 21 than is the first mounting surface 112.

As shown in FIGS. 31 and 32, the fourth terminals 14 include two fourth terminals each of which has a second sub-mounting surface 145. The second sub-mounting surface 145 is exposed from the bottom surface 42 of the sealing resin 40. Each of the two fourth terminals 14 is configured such that, on the bottom surface 42 of the sealing resin 40, the second sub-mounting surface 145 is positioned farther inward than the fourth mounting surface 142. For each of the two fourth terminals 14, the dimension of the second sub-mounting surface 145 in the second direction y is less than the dimension of the fourth mounting surface 142 in the second direction y. For each of the two fourth terminals 14, the second sub-mounting surface 145 is positioned closer to the first exposed surface 212 of the first lead 21 than is the fourth mounting surface 142.

The following describes effects of the semiconductor device A60.

The semiconductor device A60 includes a first terminal 11, a second terminal 12, a third terminal 13, a fourth terminal 14, a first lead 21, a second lead 22, a semiconductor element 30, and a sealing resin 40. The first lead 21 has a first exposed surface 212 with a dimension D1, and the first terminal 11 has a first mounting surface 112 with a dimension L1, where the dimension D1 is greater than the dimension L1. The second lead 22 has a second exposed surface 222 with a dimension D2, and the second terminal 12 has a second mounting surface 122 with a dimension L2, where the dimension D2 is greater than the dimension L2. As viewed in the third direction z, the first end 212A of the first exposed surface 212 and the third end 222A of the second exposed surface 222 are positioned inward of the perimeter 401 of the sealing resin 40. As viewed in the third direction z, the fourth end 222B of the second exposed surface 222 overlaps with the perimeter 401 of the sealing resin 40. The semiconductor device A60 of this configuration ensures that the thermal stress on the plurality of terminals is more uniform. Additionally, the semiconductor device A60 has a configuration in common with the semiconductor device A10, thereby achieving the same effect as the semiconductor device A10.

The first terminal 11 has a first sub-mounting surface 115 that is exposed from the bottom surface 42 of the sealing resin 40. On the bottom surface 42, the first sub-mounting surface 115 is positioned farther inward than the first mounting surface 112 of the first terminal 11. This configuration reduces deflection of the first terminal 11about an axis perpendicular to the third direction z when an electrode 31 of the semiconductor element 30 is electrically bonded to the first terminal 11. This consequently prevents a decrease in the bonding strength of the semiconductor element 30 to the first terminal 11.

The present disclosure is not limited to the foregoing embodiments. Various modifications in design may be made freely in the specific structure of each part of the present disclosure.

The present disclosure includes embodiments described in the following clauses.

### Clause 1

A semiconductor device comprising:
a first terminal and a fourth terminal spaced apart from each other in a first direction;
a second terminal and a third terminal spaced apart from each other in a second direction perpendicular to the first direction;
a semiconductor element electrically connected to at least one of the first terminal the second terminal, the third terminal, and the fourth terminal;
a first lead positioned next to the first terminal in the second direction and extending in the first direction;
a second lead positioned next to the second terminal in the first direction and extending in the second direction; and
a sealing resin covering the semiconductor element,
wherein the sealing resin includes a bottom surface that faces one side in a third direction perpendicular to the first direction and the second direction,
the first terminal, the second terminal, the first lead, and the second lead respectively include a first mounting surface, a second mounting surface, a first exposed surface, and a second exposed surface each of which is exposed from the bottom surface,
a dimension of the first exposed surface in the first direction is greater than a dimension of the first mounting surface in the first direction,
a dimension of the second exposed surface in the second direction is greater than a dimension of the second mounting surface in the second direction,
the first exposed surface includes a first end and a second end spaced apart from each other in the first direction,
the second exposed surface includes a third end and a fourth end spaced apart from each other in the second direction,
as viewed in the third direction, the first end and the third end are positioned inward of a perimeter of the sealing resin, and
as viewed in the third direction, the fourth end overlaps with the perimeter of the sealing resin.

### Clause 2

The semiconductor device according to Clause 1, wherein the fourth end is positioned closer to the second mounting surface than is the third end and in contact with the bottom surface.

### Clause 3

The semiconductor device according to Clause 2, wherein the dimension of the first exposed surface in the first direction is greater than the dimension of the second exposed surface in the second direction.

### Clause 4

The semiconductor device according to Clause 3, wherein as viewed in the third direction, the first exposed surface overlaps with a first center line that extends in the second direction and passes through a center of the second exposed surface in the first direction.

### Clause 5

The semiconductor device according to Clause 4, wherein the second end is positioned closer to the first mounting surface than is the first end and is in contact with the bottom surface.

### Clause 6

The semiconductor device according to Clause 4, wherein as viewed in the third direction, the second end is positioned inward of the perimeter of the sealing resin.

### Clause 7

The semiconductor device according to Clause 3, wherein as viewed in the third direction, the first exposed surface is offset from a first center line that extends in the second direction and passes through a center of the second exposed surface in the first direction.

### Clause 8

The semiconductor device according to any one of Clauses 4 to 7, further comprising a third lead positioned next to the third terminal in the first direction and extending in the second direction,
wherein the third terminal and the third lead respectively include a third mounting surface and a third exposed surface each of which is exposed from the bottom surface,
a dimension of the third exposed surface in the second direction is greater than a dimension of the third mounting surface in the second direction,
the third exposed surface includes a fifth end and a sixth end spaced apart from each other in the second direction,
as viewed in the third direction, the fifth end is positioned inward of the perimeter of the sealing resin, and
as viewed in the third direction, the sixth end overlaps with the perimeter of the sealing resin.

### Clause 9

The semiconductor device according to Clause 8, wherein the sixth end is positioned closer to the third mounting surface than is the fifth end and is in contact with the bottom surface.

### Clause 10

The semiconductor device according to Clause 9, wherein as viewed in the third direction, the third exposed surface overlaps with the first center line.

### Clause 11

The semiconductor device according to Clause 10, wherein the third end is positioned closer to the first exposed surface than is the fifth end.

### Clause 12

The semiconductor device according to Clause 10, wherein as viewed in the third direction, the first center line intersects a second center line that extends in the first direction and passes through a center of the first exposed surface in the second direction, and as viewed in the third direction, a distance between an intersection point of the first center line and the second center line and a center of the bottom surface is less than or equal to the dimension of the first mounting surface in the first direction.

### Clause 13

The semiconductor device according to Clause 9, wherein as viewed in the third direction, the third exposed surface is offset from the first center line.

### Clause 14

The semiconductor device according to Clause 9, wherein the semiconductor element includes a plurality of electrodes positioned on a side facing the first terminal, the second terminal, the third terminal, and the fourth terminal in the third direction, and one of the plurality of electrodes is electrically bonded to one of the first terminal, the second terminal, the third terminal, and the fourth terminal.

### Clause 15

The semiconductor device according to Clause 14, wherein one of the plurality of electrodes is electrically bonded to one of the first lead, the second lead, and the third lead.

### Clause 16

The semiconductor device according to Clause 15, wherein the sealing resin includes a first side surface that faces one side in the first direction, and
the first terminal and the first lead are exposed from the first side surface.

### Clause 17

The semiconductor device according to Clause 16, wherein the sealing resin includes a second side surface that faces one side in the second direction, and
the second terminal and the second lead are exposed from the second side surface.

### Clause 18

The semiconductor device according to Clause 17, further comprising a plurality of dummy terminals respectively positioned at four corners of the sealing resin as viewed in the third direction,
wherein each of the plurality of dummy terminals includes a dummy exposed surface that is exposed from the bottom surface.

### Clause 19

The semiconductor device according to Clause 18, wherein a dimension of the dummy exposed surface in the first direction is greater than a dimension of the second mounting surface in the first direction, and
a dimension of the dummy exposed surface in the second direction is greater than a dimension of the first mounting surface in the second direction.

### Clause 20

The semiconductor device according to Clause 9, further comprising a fourth lead positioned next to the fourth terminal in the second direction and extending in the first direction,
wherein the fourth terminal and the fourth lead respectively include a fourth mounting surface and a fourth exposed surface each of which is exposed from the bottom surface,
a dimension of the fourth exposed surface in the first direction is greater than a dimension of the fourth mounting surface in the first direction,
the fourth exposed surface includes a seventh end and an eighth end spaced apart from each other in the first direction,
as viewed in the third direction, the seventh end is positioned inward of the perimeter of the sealing resin, and
as viewed in the third direction, the eighth end overlaps with the perimeter of the sealing resin.

### Clause 21

The semiconductor device according to Clause 20, wherein the eighth end is positioned closer to the fourth mounting surface than is the seventh end and is in contact with the bottom surface.

### Clause 22

The semiconductor device according to Clause 21, wherein as viewed in the third direction, the fourth exposed surface overlaps with a second center line that extends in the first direction and passes through a center of the first exposed surface in the second direction.

### Clause 23

The semiconductor device according to Clause 22, wherein the dimension of the fourth exposed surface in the first direction is different from the dimension of the first exposed surface in the first direction.

### Clause 24

The semiconductor device according to Clause 22, wherein as viewed in the third direction, the second exposed surface and the third exposed surface are offset from the second center line.

### Clause 25

The semiconductor device according to Clause 9, wherein the first terminal includes a first sub-mounting surface that is exposed from the bottom surface, and
on the bottom surface, the first sub-mounting surface is positioned farther inward than the first mounting surface.

### Clause 26

The semiconductor device according to Clause 25, wherein a dimension of the first sub-mounting surface in the second direction is less than or equal to a dimension of the first mounting surface in the second direction.

### Clause 27

The semiconductor device according to Clause 26, wherein the first sub-mounting surface is positioned closer to the first exposed surface than is the first mounting surface.

1. A semiconductor device comprising:
a first terminal and a fourth terminal spaced apart from each other in a first direction;
a second terminal and a third terminal spaced apart from each other in a second direction perpendicular to the first direction;
a semiconductor element electrically connected to at least one of the first terminal, the second terminal, the third terminal, and the fourth terminal;
a first lead positioned next to the first terminal in the second direction and extending in the first direction;
a second lead positioned next to the second terminal in the first direction and extending in the second direction; and
a sealing resin covering the semiconductor element,
wherein the sealing resin includes a bottom surface that faces one side in a third direction perpendicular to the first direction and the second direction,
the first terminal, the second terminal, the first lead, and the second lead respectively include a first mounting surface, a second mounting surface, a first exposed surface, and a second exposed surface each of which is exposed from the bottom surface,
a dimension of the first exposed surface in the first direction is greater than a dimension of the first mounting surface in the first direction,
a dimension of the second exposed surface in the second direction is greater than a dimension of the second mounting surface in the second direction,
the first exposed surface includes a first end and a second end spaced apart from each other in the first direction,
the second exposed surface includes a third end and a fourth end spaced apart from each other in the second direction,
as viewed in the third direction, the first end and the third end are positioned inward of a perimeter of the sealing resin, and
as viewed in the third direction, the fourth end overlaps with the perimeter of the sealing resin.

2. The semiconductor device according to claim 1, wherein the fourth end is positioned closer to the second mounting surface than is the third end and in contact with the bottom surface.

3. The semiconductor device according to claim 2, wherein the dimension of the first exposed surface in the first direction is greater than the dimension of the second exposed surface in the second direction.

4. The semiconductor device according to claim 3, wherein as viewed in the third direction, the first exposed surface overlaps with a first center line that extends in the second direction and passes through a center of the second exposed surface in the first direction.

5. The semiconductor device according to claim 4, wherein the second end is positioned closer to the first mounting surface than is the first end and is in contact with the bottom surface.

6. The semiconductor device according to claim 4, wherein as viewed in the third direction, the second end is positioned inward of the perimeter of the sealing resin.

7. The semiconductor device according to claim 3, wherein as viewed in the third direction, the first exposed surface is offset from a first center line that extends in the second direction and passes through a center of the second exposed surface in the first direction.

8. The semiconductor device according to claim 4, further comprising a third lead positioned next to the third terminal in the first direction and extending in the second direction,
wherein the third terminal and the third lead respectively include a third mounting surface and a third exposed surface each of which is exposed from the bottom surface,
a dimension of the third exposed surface in the second direction is greater than a dimension of the third mounting surface in the second direction,
the third exposed surface includes a fifth end and a sixth end spaced apart from each other in the second direction,
as viewed in the third direction, the fifth end is positioned inward of the perimeter of the sealing resin, and
as viewed in the third direction, the sixth end overlaps with the perimeter of the sealing resin.

9. The semiconductor device according to claim 8, wherein the sixth end is positioned closer to the third mounting surface than is the fifth end and is in contact with the bottom surface.

10. The semiconductor device according to claim 9, wherein as viewed in the third direction, the third exposed surface overlaps with the first center line.

11. The semiconductor device according to claim 10, wherein the third end is positioned closer to the first exposed surface than is the fifth end.

12. The semiconductor device according to claim 10, wherein as viewed in the third direction, the first center line intersects a second center line that extends in the first direction and passes through a center of the first exposed surface in the second direction, and as viewed in the third direction, a distance between an intersection point of the first center line and the second center line and a center of the bottom surface is less than or equal to the dimension of the first mounting surface in the first direction.

13. The semiconductor device according to claim 9, wherein as viewed in the third direction, the third exposed surface is offset from the first center line.

14. The semiconductor device according to claim 9, wherein
the semiconductor element includes a plurality of electrodes positioned on a side facing the first terminal, the second terminal, the third terminal, and the fourth terminal in the third direction, and
one of the plurality of electrodes is electrically bonded to one of the first terminal, the second terminal, the third terminal, and the fourth terminal.

15. The semiconductor device according to claim 14, wherein one of the plurality of electrodes is electrically bonded to one of the first lead, the second lead, and the third lead.

16. The semiconductor device according to claim 15, wherein
the sealing resin includes a first side surface that faces one side in the first direction, and
the first terminal and the first lead are exposed from the first side surface.

17. The semiconductor device according to claim 16, wherein
the sealing resin includes a second side surface that faces one side in the second direction, and
the second terminal and the second lead are exposed from the second side surface.

18. The semiconductor device according to claim 17, further comprising a plurality of dummy terminals respectively positioned at four corners of the sealing resin as viewed in the third direction,
wherein each of the plurality of dummy terminals includes a dummy exposed surface that is exposed from the bottom surface.

19. The semiconductor device according to claim 18, wherein
a dimension of the dummy exposed surface in the first direction is greater than a dimension of the second mounting surface in the first direction, and
a dimension of the dummy exposed surface in the second direction is greater than a dimension of the first mounting surface in the second direction.
